(19) United States
(12) Patent Application Publication
(10) Pub. No.: US 2026/0144029 A1
(43) Pub. Date: May 21, 2026

(54) FABRICATION METHOD FOR SEMICONDUCTOR STRUCTURE AND SEMICONDUCTOR STRUCTURE

(71) Applicant: CXMT Corporation, Hefei City (CN)

(72) Inventor: Peng REN, Hefei City (CN)

(73) Assignee: CXMT Corporation, Hefei City (CN)

(21) Appl. No.: 19/238,614

(22) Filed: Jun. 16, 2025

Related U.S. Application Data
(63) Continuation of application No. PCT/CN2025/082239, filed on Mar. 13, 2025.

(30) Foreign Application Priority Data
Nov. 21, 2024 (CN) 202411679081.2

(51) Int. Cl. H01L 21/768; H01L 23/522

(52) U.S. Cl. CPC H10W 20/038; H10W 20/056; H10W 20/062; H10W 20/42

(57) ABSTRACT

A fabrication method for a semiconductor structure and a semiconductor structure are provided. The fabrication method includes the steps as follows. A base is provided, where a first trench is formed on the base, and a first initial conductive structure fills the first trench and covers the surface of the base; a part of the first initial conductive structure is removed by adopting a first polishing process to form a first conductive structure, where the first conductive structure is located in the first trench, and the surface of the first conductive structure has a first dishing; a barrier layer is formed, where the barrier layer covers at least the first dishing; and a second conductive structure is formed on the barrier layer, where the second conductive structure is electrically connected to the barrier layer.

### CROSS-REFERENCE TO RELATED APPLICATIONS

This application is a continuation of International Patent Application No. PCT/CN 2025/082239 filed on Mar. 13, 2025, which claims priority to Chinese Patent Application No. 202411679081.2 filed on Nov. 21, 2024. The disclosures of the above-referenced applications are hereby incorporated by reference in their entirety.

### BACKGROUND

In the fabrication procedure of a DRAM, the BEOL stage is mainly responsible for fabricating metal interconnection. In this stage, some metals are adopted as interconnection materials. However, in a conventional process procedure, some problems exist in interconnection of different metals. Due to differences in electrochemical properties of the different metals, it is easy to generate electrochemical reaction under a specific condition. This reaction possibly causes metal migration and corrosion. In addition, metal diffusion and migration also exist at an interface between a metal and a dielectric material. These problems seriously affect the performance and the reliability of the DRAM.

### SUMMARY

Embodiments of the present disclosure relate to the semiconductor field, and in particular, to a fabrication method for a semiconductor structure and a semiconductor structure.

Embodiments of the present disclosure provide a fabrication method for a semiconductor structure and a semiconductor structure, which at least helps avoid problems such as metal migration, diffusion, and corrosion, and improve the performance of a semiconductor memory device and increase the yield thereof.

According to some embodiments of the present disclosure, one aspect of the embodiments of the present disclosure provides a fabrication method for a semiconductor structure, including the steps as follows. A base is provided, where a first trench is formed on the base, and a first initial conductive structure fills the first trench and covers the surface of the base; a part of the first initial conductive structure is removed by adopting a first polishing process to form a first conductive structure, where the first conductive structure is located in the first trench, and the surface of the first conductive structure has a first dishing; a barrier layer is formed, where the barrier layer covers at least the first dishing; and a second conductive structure is formed on the barrier layer, where the second conductive structure is electrically connected to the barrier layer.

Another aspect of the embodiments of the present disclosure provides a semiconductor structure, including: a base, where the base has a first trench;
a first conductive structure, located in the first trench, where the surface of the first conductive structure has a first dishing; a barrier layer, covering at least the first dishing; and a second conductive structure, located above the barrier layer and electrically connected to the barrier layer.

The technical solutions provided in the embodiments of the present disclosure have at least the following advantages: The barrier layer is disposed on the first conductive structure, and the air gap structures are disposed on a corner of the first conductive structure, to prevent diffusion and migration of the first conductive structure and corrosion of the second conductive structure, thereby improving the performance of the semiconductor structure.

### BRIEF DESCRIPTION OF DRAWINGS

One or more embodiments are exemplified with the figures in the accompanying drawings corresponding to the one or more embodiments. These example descriptions are not intended to limit the embodiments, and unless specifically stated, no scale limitations are constituted by the figures in the accompanying drawings. To describe the technical solutions in the embodiments of the present disclosure or the conventional technologies more clearly, the accompanying drawings required by the embodiments are briefly described below. Clearly, the accompanying drawings in the following description show merely some embodiments of the present disclosure, and other drawings may be obtained by a person of ordinary skill in the art from these accompanying drawings without creative efforts.

FIG. 1A is a first process flowchart of a fabrication method for a semiconductor structure according to an implementation;

FIG. 1B is a second process flowchart of a fabrication method for a semiconductor structure according to an implementation;

FIG. 1C is a third process flowchart of a fabrication method for a semiconductor structure according to an implementation;

FIG. 1D is a fourth process flowchart of a fabrication method for a semiconductor structure according to an implementation;

FIG. 2A is a first process flowchart of a fabrication method for a semiconductor structure according to an embodiment of the present disclosure;

FIG. 2B is a second process flowchart of a fabrication method for a semiconductor structure according to an embodiment of the present disclosure;

FIG. 2C is a third process flowchart of a fabrication method for a semiconductor structure according to an embodiment of the present disclosure;

FIG. 2D is a fourth process flowchart of a fabrication method for a semiconductor structure according to an embodiment of the present disclosure;

FIG. 2E is a fifth process flowchart of a fabrication method for a semiconductor structure according to an embodiment of the present disclosure;

FIG. 2F is a sixth process flowchart of a fabrication method for a semiconductor structure according to an embodiment of the present disclosure;

FIG. 2G is a seventh process flowchart of a fabrication method for a semiconductor structure according to an embodiment of the present disclosure;

FIG. 2H is an eighth process flowchart of a fabrication method for a semiconductor structure according to an embodiment of the present disclosure;

FIG. 2I is a nineth process flowchart of a fabrication method for a semiconductor structure according to an embodiment of the present disclosure;

FIG. 2J is a tenth process flowchart of a fabrication method for a semiconductor structure according to an embodiment of the present disclosure;

FIG. 2K is an eleventh process flowchart of a fabrication method for a semiconductor structure according to an embodiment of the present disclosure;

FIG. 2L is a twelfth process flowchart of a fabrication method for a semiconductor structure according to an embodiment of the present disclosure;

FIG. 2M is a thirteenth process flowchart of a fabrication method for a semiconductor structure according to an embodiment of the present disclosure;

FIG. 2N is a fourteenth process flowchart of a fabrication method for a semiconductor structure according to an embodiment of the present disclosure;

FIG. 2O is a fifteenth process flowchart of a fabrication method for a semiconductor structure according to an embodiment of the present disclosure;

FIG. 2P is a sixteenth process flowchart of a fabrication method for a semiconductor structure according to an embodiment of the present disclosure;

FIG. 2Q is a seventeenth process flowchart of a fabrication method for a semiconductor structure according to an embodiment of the present disclosure;

FIG. 2R is an eighteenth process flowchart of a fabrication method for a semiconductor structure according to an embodiment of the present disclosure;

FIG. 3A is a first process flowchart of a fabrication method for a semiconductor structure according to another embodiment of the present disclosure;

FIG. 3B is a second process flowchart of a fabrication method for a semiconductor structure according to another embodiment of the present disclosure;

FIG. 3C is a third process flowchart of a fabrication method for a semiconductor structure according to another embodiment of the present disclosure;

FIG. 3D is a fourth process flowchart of a fabrication method for a semiconductor structure according to another embodiment of the present disclosure;

FIG. 4 is a schematic diagram of a semiconductor structure according to an embodiment of the present disclosure; and

FIG. 5 is a schematic diagram of a semiconductor structure according to another embodiment of the present disclosure.

### DETAILED DESCRIPTION

It may be learned from the background that in the fabrication procedure of a DRAM, the BEOL stage is mainly responsible for fabricating metal interconnection. In this stage, some metals are adopted as interconnection materials. However, in a conventional process procedure, some problems exist in interconnection of different metals. Due to differences in electrochemical properties of the different metals, it is easy to generate electrochemical reaction under a specific condition. This reaction possibly causes metal migration and corrosion. In addition, metal diffusion also exists at an interface between a metal and a dielectric material. These problems seriously affect the performance and the reliability of the DRAM.

Embodiments of the present disclosure provide a fabrication method for a semiconductor structure and a semiconductor structure. A barrier layer is disposed on a first conductive structure, and air gap structures are disposed on a corner of the first conductive structure, to prevent diffusion and migration of the first conductive structure and corrosion of the second conductive structure, thereby improving the performance of the semiconductor structure.

The embodiments of the present disclosure are described in detail below with reference to the accompanying drawings. However, it may be understood by a person of ordinary skill in the art that in the embodiments of the present disclosure, many technical details are provided to enable readers to better understand the present disclosure. However, the technical solutions claimed in the present disclosure may be implemented even without these technical details and various variations and modifications made based on the following embodiments. In the following paragraphs, the present disclosure is described more specifically by way of example with reference to the accompanying drawings. The advantages and features of the present disclosure will be clearer from the following description and claims. It should be noted that the accompanying drawings are presented in a highly simplified form and are not drawn to exact scale, and are merely intended to conveniently and clearly assist in describing the embodiments of the present disclosure.

It may be understood that meanings of “on”, “over”, and “above” in the present disclosure should be understood in the broadest sense, so that “on” means that it is “on” something with no intermediate feature or layer (that is, directly on something), and further includes the meaning that it is “on” something with an intermediate feature or layer.

In the embodiments of the present disclosure, the terms “first”, “second”, “third”, and the like are intended to distinguish between similar objects but do not necessarily indicate a specific order or sequence.

In the embodiments of the present disclosure, the term “layer” refers to a material part including a region having a thickness. The layer may extend over the whole of a lower or upper structure, or may have a range smaller than the range of the lower or upper structure. In addition, the layer may be a region of a homogeneous or heterogeneous continuous structure whose thickness is less than the thickness of a continuous structure. For example, the layer may be located between the top surface and the bottom surface of the continuous structure, or the layer may be located between any horizontal surface pair at the top surface and the bottom surface of the continuous structure. The layer may extend horizontally, vertically, and/or along an inclined surface. The layer may include multiple sublayers.

It should be noted that the technical solutions described in the embodiments of the present disclosure may be randomly combined when there is no conflict.

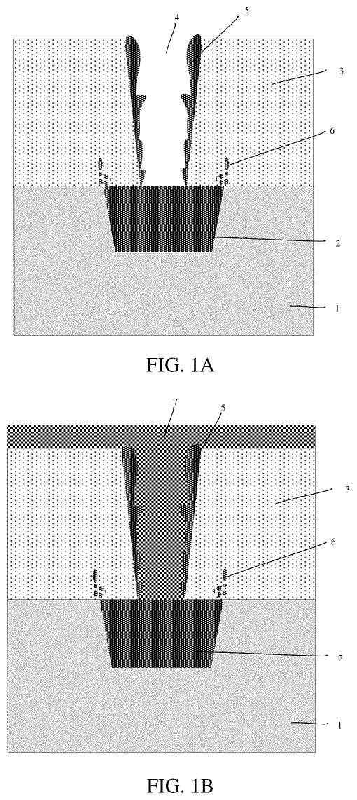

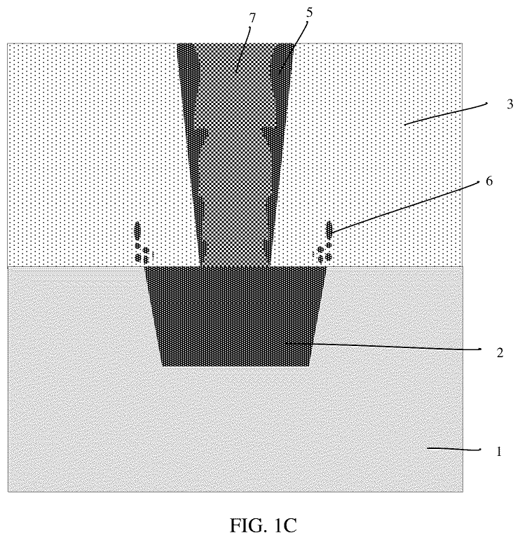

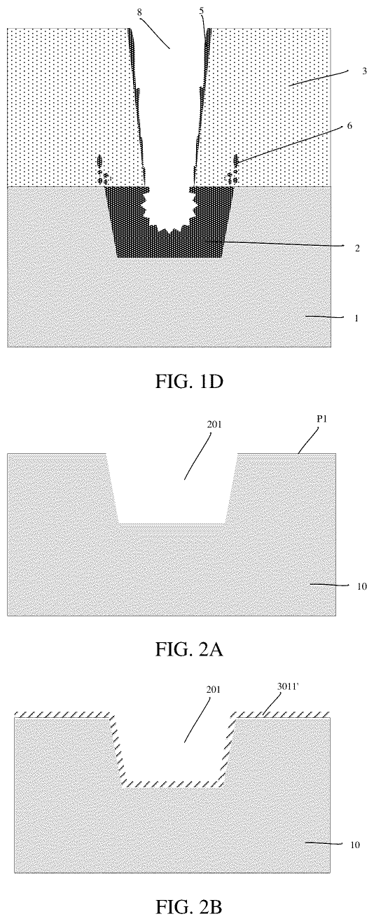

FIG. 1A to FIG. 1D are process flowcharts of a fabrication method for a semiconductor structure according to an implementation.

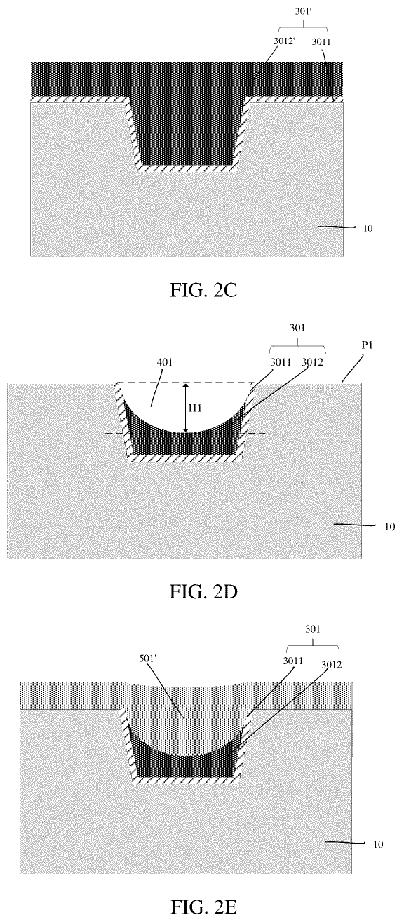

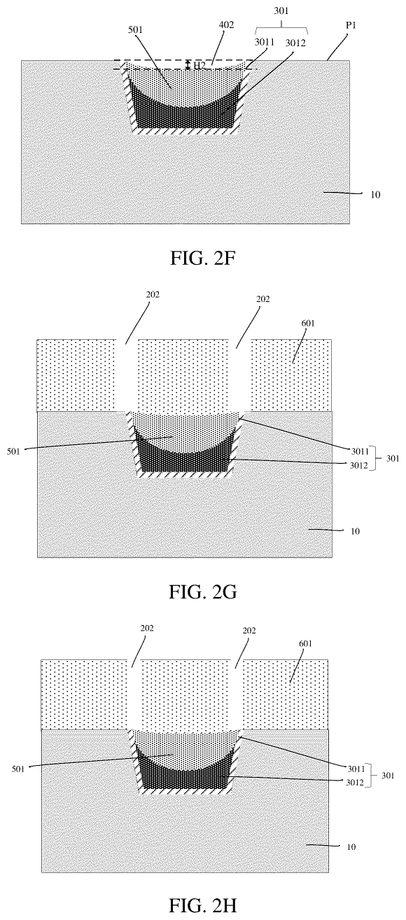

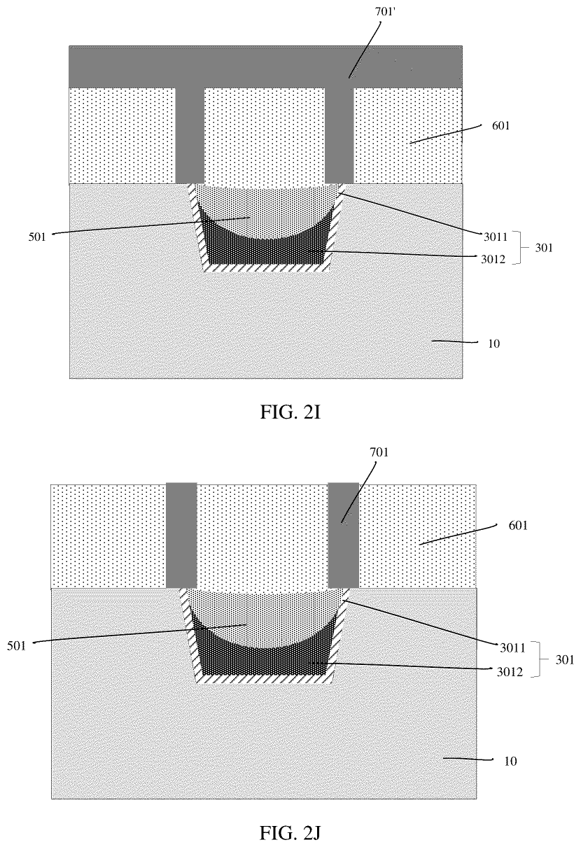

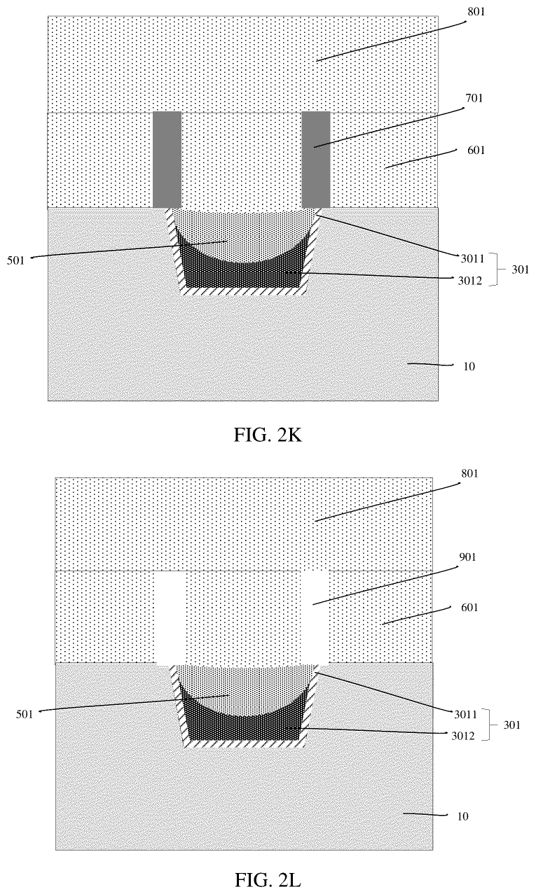

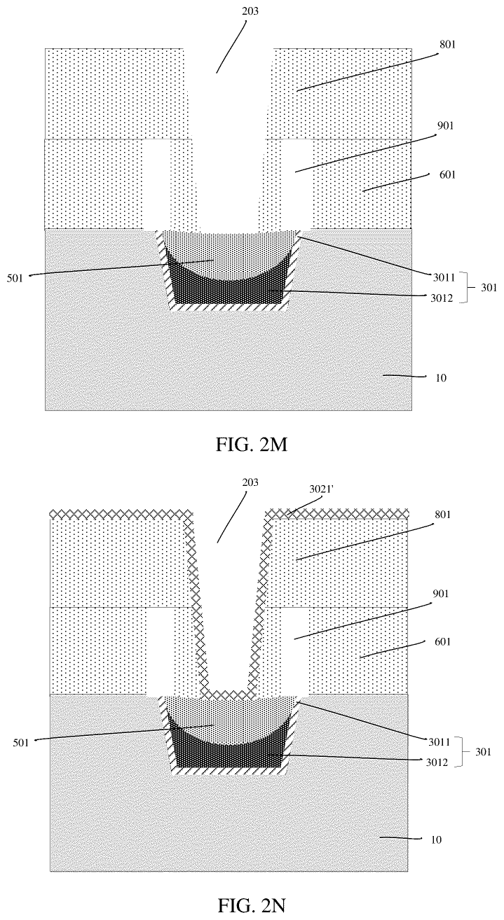

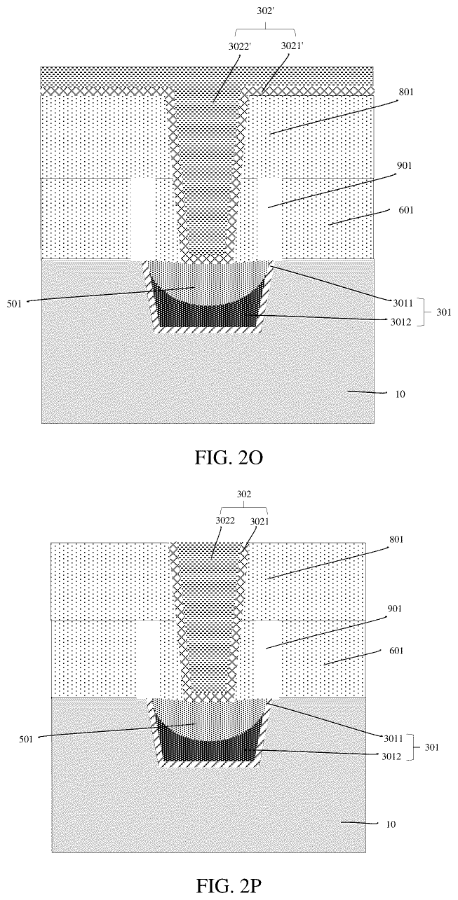

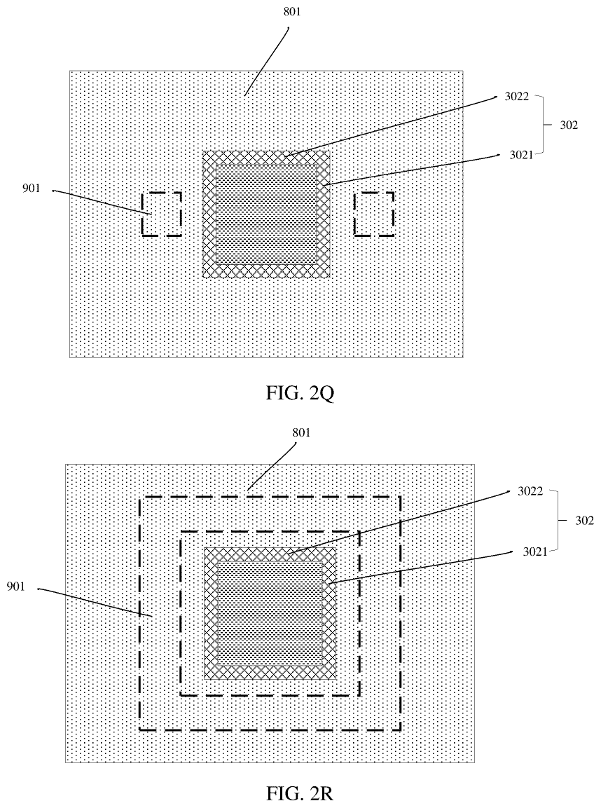

FIG. 2A to FIG. 2R are process flowcharts of a fabrication method for a semiconductor structure according to an embodiment of the present disclosure.

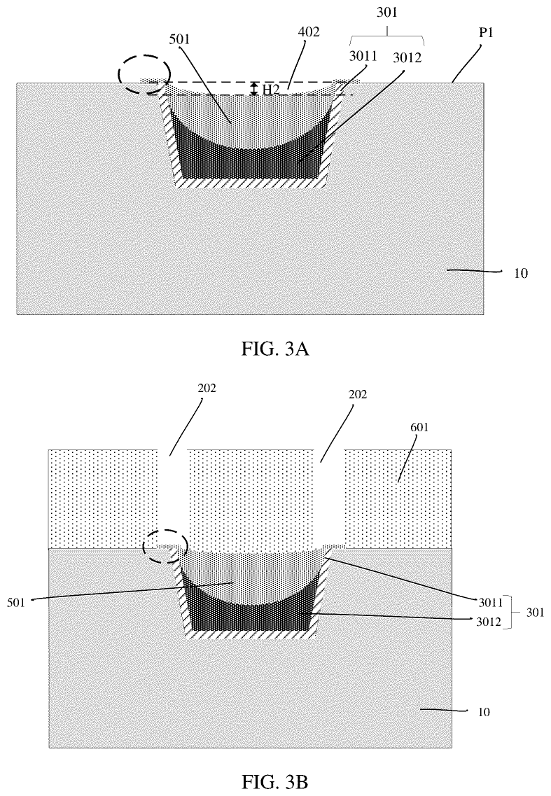

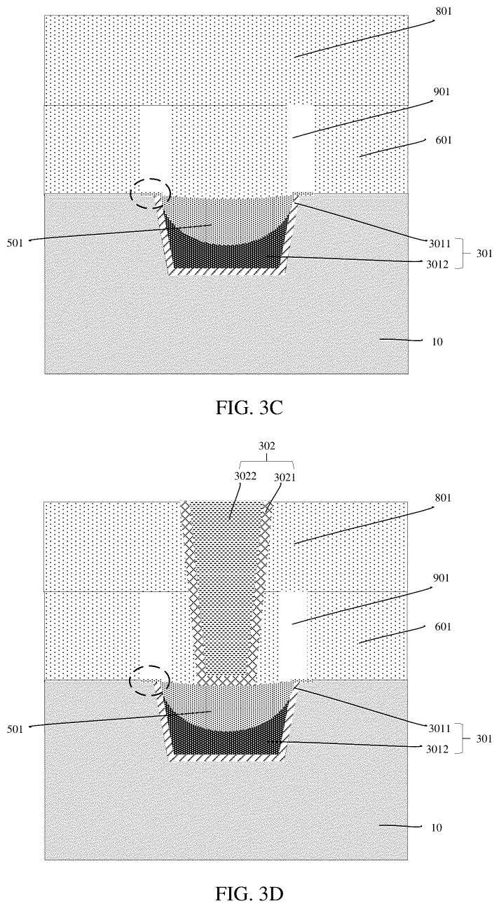

FIG. 3A to FIG. 3D are process flowcharts of a fabrication method for a semiconductor structure according to another embodiment of the present disclosure.

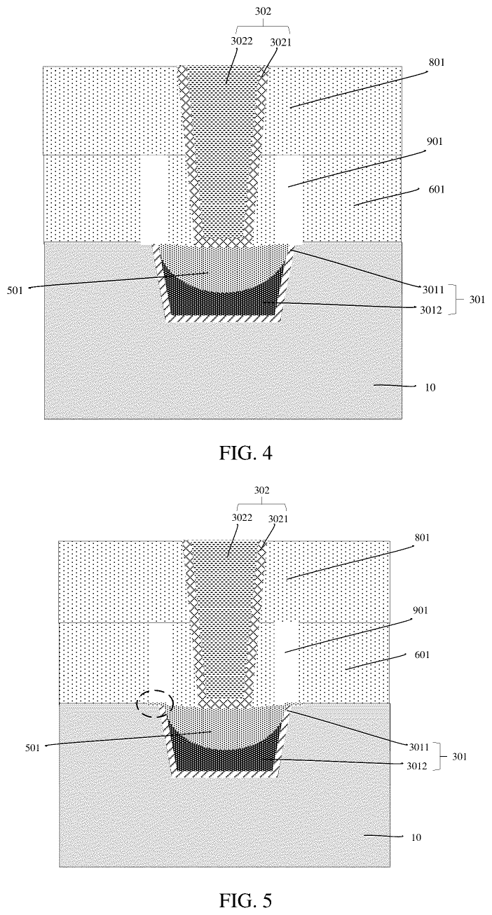

FIG. 4 is a schematic diagram of a semiconductor structure according to an embodiment of the present disclosure.

FIG. 5 is a schematic diagram of a semiconductor structure according to another embodiment of the present disclosure.

As shown in FIG. 1A to FIG. 1D, for details, refer to FIG. 1A first. A semiconductor structure includes a base 1, a first conductive structure 2 is provided in the base 1, a dielectric layer 3 is provided on the base 1, and the dielectric layer 3 has a first opening 4. A diffusion structure 5 exists on a sidewall of the first opening 4 due to diffusion of the first conductive structure 2, and the diffusion structure 5 possibly protrudes from the top surface of the dielectric layer 3. In addition, a migration structure 6 also exists in the dielectric layer 3 due to a migration action of the first conductive structure 2. Both the material of the diffusion structure 5 and the material of the migration structure 6 are the same as the material of the first conductive structure 2. Next, refer to FIG. 1B and FIG. 1C first. A second conductive structure 7 is formed in the first opening 4, and the second conductive structure 7 further covers the surface of the dielectric layer 3. A part of the second conductive structure 7 above the dielectric layer 3 is removed, so that the diffusion structure 5 is exposed. Next, refer to FIG. 1D first. The diffusion structure 5 is exposed. Due to different chemical activities of the diffusion structure 5 and the second conductive structure 7, in a subsequent wet cleaning procedure, the diffusion structure 5 and the second conductive structure 7 constitute a primary cell structure, and electrochemical reaction generates. The electrochemical reaction accelerates corrosion of the second conductive structure 7, and further, the first conductive structure 2 is corroded to form a second opening 8. Originally, the first conductive structure 2 and the second conductive structure 7 serve as interconnection metal layers for signal conduction. The second conductive structure 7 is removed due to diffusion of the first conductive structure 2, and the first conductive structure 2 is also corroded, which causes signal interruption and affects the performance of the semiconductor structure. In addition, the presence of the migration structure 6 affects the performance between adjacent interconnection structures, and possibly causes a short circuit between adjacent second conductive structures 7 or adjacent first conductive structures 2, or a short circuit between the second conductive structure 7 and the first conductive structure 2 that are adjacent to each other. This further affects the performance of the semiconductor structure, and reduces the product yield.

FIG. 2A to FIG. 2R are process flowcharts of a fabrication method for a semiconductor structure according to an embodiment of the present disclosure.

Specifically, refer to FIG. 2A. A base 10 is provided. The base 10 has a first top surface P1, and a first trench 201 is formed on the base 10. The material of the base 10 is a non-conductive material, which may be specifically silicon oxide, silicon nitride, silicon oxynitride, or silicon carbide nitride.

Next, refer to FIG. 2B and FIG. 2C. A first initial conductive structure 301′ is filled in the first trench 201, and the first initial conductive structure 301′ fills the first trench 201 and covers the surface of the base 10. The first initial conductive structure 301′ includes a first initial conductive sub-structure 3011′ and a second initial conductive sub-structure 3012′. Specifically, as shown in FIG. 2B, first, the first initial conductive sub-structure 3011′ is formed in the first trench 201, and the first initial conductive sub-structure 3011′ covers a sidewall and the bottom of the first trench 201 and covers the surface of the base 10. Then, the second initial conductive sub-structure 3012′ is formed on the first initial conductive sub-structure 3011′, and the second initial conductive sub-structure 3012′ fills the remaining part of the first trench 201 and covers the first initial conductive sub-structure 3011′ on the base 10. The first initial conductive sub-structure 3011′ and the second initial conductive sub-structure 3012′ together constitute the first initial conductive structure 301′.

Next, refer to FIG. 2D. A part of the first initial conductive structure 301′ is removed by adopting a first polishing process to form a first conductive structure 301, the first conductive structure 301 is located in the first trench 201, and the surface of the first conductive structure 301 has a first dishing 401. In a specific embodiment, the first conductive structure 301 includes a first conductive sub-structure 3011 and a second conductive sub-structure 3012, the first conductive sub-structure 3011 covers the sidewall and the bottom of the first trench 201, and the second conductive sub-structure 3012 is located in the first trench 401 and has the first dishing 401. The dishing depth of the first dishing 401 is H1. It should be noted that the dishing depth of the first dishing 401 is the depth from the first top surface P1 to the deepest bottom of the first dishing 401. Specifically, the first polishing process is a high dishing chemical mechanical polishing (High Dishing CMP) process. The selectivity ratio of the first initial conductive structure 301′ to the base 10 by the first polishing process is greater than 3:1. In other words, in a procedure of the first polishing process, the first initial conductive structure 301′ may be more removed, and a removal rate of the base 10 is relatively low. The selectivity ratio of a polishing solution is adjusted in the range of 0.005 to 200. The high dishing chemical mechanical polishing (High Dishing CMP) process adopts a specific polishing condition and process to achieve efficient planarization of a high protrusion part, while controlling the degree of dishing (Dishing). The dishing refers to a phenomenon that a planar region sinks relative to a surrounding region in a planarization procedure. In a high-density integrated circuit, controlling the degree of the dishing is critical to maintaining good electrical performance and reliability.

Next, refer to FIG. 2E and FIG. 2F. An initial barrier layer 501′ is formed, and the initial barrier layer 501′ fills the first dishing 401 and covers the base 10. A part of the initial barrier layer 501′ is removed by adopting a second polishing process to form a barrier layer 501. The barrier layer 501 covers at least the first dishing 401, the barrier layer 501 is located in the first dishing 401, and the surface of the barrier layer 501 has a second dishing 402. The dishing depth of the second dishing 402 is H2, and H1 is greater than H2. It should be noted that the dishing depth of the second dishing 402 is the depth from the first top surface P1 to the deepest bottom of the second dishing 402. Both the bottom of the first dishing 401 and the bottom of the second dishing 402 are lower than the first top surface P1. The second polishing process is a low dishing chemical mechanical polishing process (Low Dishing CMP Process). A selectivity ratio of the initial barrier layer 501′ to the base 10 by the second polishing process is less than 1.5:1, and a selectivity ratio of a polishing solution is adjusted in the range of 0.005 to 200. In other words, in a procedure of the second polishing process, a difference in removal rates of the initial barrier layer 501′ and the base 10 is not significant. However, because the removal rate of the initial barrier layer 501′ is slightly higher than the removal rate of the base 10, a polishing condition and a polishing process are controlled to achieve efficient planarization of a material. In addition, the degree of dishing is minimized, so that the dishing depth H2 of the second dishing 402 is less than the dishing depth H1 of the first dishing 401. Minimizing the dishing can reduce damage to a structure, to improve the performance and the reliability of an integrated circuit.

The barrier layer 501 covers at least the first dishing 401, that is, the barrier layer 501 covers the first conductive structure 301. In a specific embodiment, the material of the barrier layer 501 may be one or more of tantalum, tantalum nitride, ruthenium, and ruthenium nitride. The material of the first conductive sub-structure 3011 may be tantalum or tantalum nitride, and the material of the second conductive sub-structure 3012 may be copper. Because copper is easy to diffuse and migrate and to generate electrochemical reaction with the second conductive structure formed subsequently, which causes corrosion of the second conductive structure or corrosion of the first conductive structure, affecting the performance of the semiconductor structure. In this application, the material of the barrier layer 501 may be one or more of tantalum, tantalum nitride, ruthenium, and ruthenium nitride. Serving as good barrier materials, tantalum, tantalum nitride, ruthenium, and ruthenium nitride can block diffusion of the first conductive structure 301, and can prevent generation of electrochemical reaction and corrosion of a metal. Specifically, the resistivity of ruthenium is about 12.5×10\hat{ }−8 Ω·m, the resistivity of ruthenium nitride is from 10\hat{ }−6 Ω·m to 10\hat{ }−6 Ω·m, the resistivity of tantalum is about 13.7×10\hat{ }−8 Ω·m, and the resistivity of tantalum nitride is usually from 10\hat{ }−6 Ω·m to 10\hat{ }−5 Ω·m. A required barrier material may be selected according to a requirement in an actual process procedure.

Then, as shown in FIG. 2P, a second conductive structure 302 is formed on the barrier layer 501, and the second conductive structure 302 is electrically connected to the barrier layer 501.

Specifically, refer to FIG. 2G to FIG. 2L. After the barrier layer 501 is formed and before the second conductive structure 302 is formed, the method further includes the step as follows. Air gap structures 901 are formed, where the air gap structures 901 expose at least the first conductive sub-structure 3011 and a part of the barrier layer 501.

That air gap structures 901 are formed specifically includes the steps as follows. As shown in FIG. 2G, a first dielectric layer 601 is formed on the barrier layer 501, and a part of the first dielectric layer 601 is removed to form a second groove 202, where the second groove 202 exposes at least the first conductive sub-structure 3011 and a part of the barrier layer 501. In some embodiments, as shown in FIG. 2H, the second groove 202 exposes the first conductive sub-structure 3011 and the part of the barrier layer 501. In some other embodiments, as shown in FIG. 2G, the second groove 202 further exposes a part of the surface of the base in addition to the first conductive sub-structure 3011 and the part of the barrier layer 501. In a subsequent process procedure, FIG. 2G is taken as an example. It should be noted that the subsequent process procedure may alternatively be performed by taking FIG. 2H as an example. Next, still refer to FIG. 2I and FIG. 2J. An initial sacrificial layer 701′ is first formed, where the initial sacrificial layer 701′ fills the second groove 202 and covers the surface of the first dielectric layer 601; the initial sacrificial layer 701′ above the surface of the first dielectric layer 601 is removed; and the initial sacrificial layer 701′ in the second groove 202 is reserved, where the remaining part of the initial sacrificial layer 701′ serves as a sacrificial layer 701, and the sacrificial layer 701 fills the second groove. Then, as shown in FIG. 2K, a second dielectric layer 801 is formed on the sacrificial layer 701 and the first dielectric layer 601. As shown in FIG. 2L, the sacrificial layer 701 is removed by adopting an ashing process to form the air gap structures 901, where the air gap structures 901 are located in the first dielectric layer 601. The air gap structures 901 expose at least the first conductive sub-structure 3011 and a part of the barrier layer 501. Specifically, as shown in FIG. 2L, the air gap structures 901 further expose a part of the base 10 in addition to the first conductive sub-structure 3011 and the part of the barrier layer 501. Specifically, the material of the sacrificial layer 701 may be a spin-on carbon (SOC) hard mask. In an ashing procedure, oxidizing gases such as oxygen are usually adopted to chemically react with organic carbon in an SOC layer. Under high temperature and plasma conditions, oxygen may oxidize organic carbon to carbon dioxide (CO2) and water (H2O). These products are gases and may be extracted, thereby implementing removal of the SOC layer.

Next, refer to FIG. 2M to FIG. 2P. After the air gap structures 901 are formed, the method further includes the steps as follows. A third trench 203 is formed, where the third trench 203 is located between the air gap structures 901, and the third trench 203 passes through the first dielectric layer 601 and the second dielectric layer 801 and exposes the barrier layer 501; and the second conductive structure 302 is formed in the third trench 203, where the air gap structures 901 are located on at least two sides of the second conductive structure 302. Specifically, as shown in FIG. 2N, after the third trench 203 is formed, a third initial conductive sub-structure 3021′ is first formed through depositing, where the third initial conductive sub-structure 3021′ covers a sidewall and the bottom of the third trench 203, and covers the second dielectric layer 801. Then, as shown in FIG. 2O, a fourth initial conductive sub-structure 3022′ continues to be deposited, where the fourth initial conductive sub-structure 3022′ fills a remaining part of the third trench 203 and covers the third initial conductive sub-structure 3021′ above the second dielectric layer 801. Then, as shown in FIG. 2P, the third initial conductive sub-structure 3021′ and the fourth initial conductive sub-structure 3022′ that are above the second dielectric layer 801 are removed, the remaining part of the third initial conductive sub-structure 3021′ serves as a third conductive sub-structure 3021, and the remaining part of the fourth initial conductive sub-structure 3022′ serves as a fourth conductive sub-structure 3022. The third conductive sub-structure 3021 and the fourth conductive sub-structure 3022 together constitute the second conductive structure 302. The third conductive sub-structure 3021 covers the sidewall and the bottom of the third trench 203, and the fourth conductive sub-structure 3022 fills the third trench 203. The material of the third conductive sub-structure 3021 may be titanium nitride or tungsten nitride, and the material of the fourth conductive sub-structure 3022 may be tungsten. It may be learned from the foregoing description that the material of the second conductive sub-structure 3012 may be copper. Because copper is easy to diffuse and migrate and generates electrochemical reaction with tungsten of the fourth conductive sub-structure 3022, which causes corrosion of the second conductive structure 302 or corrosion of the first conductive structure 301, affecting the performance of a semiconductor structure plate. In this application, the barrier layer 501 is disposed on the first conductive structure 301, so that diffusion of copper can be prevented, and generation of electrochemical reaction and corrosion of copper or tungsten can be prevented.

Both FIG. 2Q and FIG. 2R are schematic top views of FIG. 2P. Dotted lines show the air gap structures 901. In a specific embodiment, refer FIG. 2P and FIG. 2Q. There are two air gap structures 901, and the air gap structures 901 expose the first conductive sub-structure 3011, the part of the barrier layer 501, and the part of the base 10. It may be learned from the foregoing description that the barrier layer 501 covers at least the first dishing 401, that is, the barrier layer 501 covers the first conductive structure 301. In this way, the barrier layer 501 can block diffusion of the first conductive structure 301, and prevent generation of electrochemical reaction and corrosion of a metal. However, because an electronic migration situation of the first conductive structure 301 still exists, and diffusion of the first conductive structure 301, e.g., diffusion of copper, may occur at a connection position between the first conductive structure 301 and the base 10 due to an untight connection. Diffusion of copper and migration of copper at a corner position of the first conductive structure 301 are the most severe. To further improve the performance of the semiconductor structure, in this application, the air gap structures 901 are disposed at the corner position of the first conductive structure 301. Existence of the air gap structures provides enough space for a diffusion or migration phenomenon that possibly exists in the first conductive structure 301. Even if diffusion or migration exists in the first conductive structure 301, the diffusion or the migration occurs in the air gap structures 901. Because the air gap structures 901 have a good insulating effect, the diffusion or the migration of the first conductive structure 301 can be prevented from affecting the semiconductor structure. In other words, in this application, on the one hand, the barrier layer 501 is disposed to prevent the diffusion or the migration of the first conductive structure 301, and on the other hand, the air gap structures 901 are further disposed in a corner region in which diffusion and migration are the most severe, thereby improving the performance of the semiconductor structure by disposing both the barrier layer 501 and the air gap structures 901.

In another specific embodiment, refer to FIG. 2P and FIG. 2R. Dotted lines show the air gap structures 901, and the air gap structures 901 surround the second conductive structure 302. Specifically, the air gap structures 901 surround corners of the first conductive structure 301, that is, the air gap structures 901 expose at least the first conductive sub-structure 3011 and the part of the barrier layer 501. In a specific embodiment, the air gap structures 901 may expose the first conductive sub-structure 3011 and the part of the barrier layer 501. For details, refer to FIG. 2H. In another specific embodiment, as shown in FIG. 2P, the air gap structures 901 may expose the first conductive sub-structure 3011, the part of the barrier layer 501, and the part of the base 10. The air gap structures 901 are disposed around and expose all corners of the first conductive structure 201. As described above, the existence of the air gap structures may provide more space for diffusion or migration that possibly exists in the first conductive structure 301. In comparison with FIG. 2Q, the air gap structures 901 provided in this embodiment have larger areas, and cover the corners of the first conductive structure 301 more comprehensively, thereby further improving the performance of the semiconductor structure.

FIG. 3A to FIG. 3D are process flowcharts of a fabrication method for a semiconductor structure according to another embodiment of the present disclosure. In this embodiment, parts same as those shown in FIG. 2A to FIG. 2R are not described again. For details, refer to the content shown in FIG. 2A to FIG. 2R. The following mainly describes a different part. Specifically, refer to FIG. 2A to FIG. 2E and FIG. 3A. In a procedure of removing a part of an initial barrier layer 501′ by adopting a second polishing process to form a barrier layer 501, the barrier layer 501 covers a part of a base 10 in addition to a first dishing 401. As in FIG. 3A, a dotted circle schematically shows that the barrier layer 501 covers the part of the base 10.

Next, refer to FIG. 3B. A second groove 202 is formed, and the second groove 202 exposes a part of the barrier layer 501. Subsequently, refer to FIG. 2H to FIG. 2K. A sacrificial layer 701 is formed in the second groove 202, and a second dielectric layer 801 is formed on the sacrificial layer 701 and a first dielectric layer 601. Next, refer to FIG. 3C. The sacrificial layer 701 is removed by adopting an ashing process to form air gap structures 901, where the air gap structures 901 are located in the first dielectric layer 601, and the air gap structures 901 expose a part of the barrier layer 501. Specifically, the air gap structures expose a part of the barrier layer 501 in the first dishing 401, and further expose a part of the barrier layer 501 on the base 10.

Then, as shown in FIG. 3D, a second conductive structure 302 is formed. The second conductive structure 302 is located between the air gap structures 901. In this embodiment, the barrier layer 501 covers a first conductive structure 301 and further covers the part of the base 10. In other words, diffusion or migration that originally possibly exists at a junction position between the first conductive structure 301 and the base 10 is directly covered by the barrier layer 501, thereby further preventing occurrence of the diffusion or the migration. In addition, the air gap structures 901 are further disposed at a corner position of the first conductive structure 301. There may be two air gap structures 901, which are located on two sides of the second conductive structure 302 and expose a corner of the first conductive structure 301. Alternatively, the air gap structures 901 may be disposed around the second conductive structure 302 and expose the corner of the first conductive structure 301. In comparison with the previous embodiment, the barrier layer 501 in this embodiment of this application further covers a first conductive sub-structure 3011 and the part of the substrate 10, to better prevent diffusion and migration of the first conductive structure 301, further prevent occurrence of electrochemical reaction, prevent corrosion of the first conductive structure 301 and the second conductive structure 302, and further improve the performance of the semiconductor structure and increase the yield thereof.

FIG. 4 is a schematic diagram of a semiconductor structure according to an embodiment of the present disclosure.

As shown in FIG. 4, the semiconductor structure includes: a base 10, where the base 10 has a first trench 201; a first conductive structure 301 is located in the first trench 201, and the surface of the first conductive structure 301 has a first dishing 401; a barrier layer 501 covers at least the first dishing 401; and a second conductive structure 302 is located above the barrier layer 501 and is electrically connected to the barrier layer 501. The surface of the barrier layer 501 has a second dishing 402, the dishing depth of the first dishing 401 is H1, the dishing depth of the second dishing 402 is H2, and H1 is greater than H2. The first conductive structure 301 includes a first conductive sub-structure 3011 and a second conductive sub-structure 3012, the first conductive sub-structure 3011 covers a sidewall and the bottom of the first trench 201, and the second conductive sub-structure 3012 is located in the first trench 201 and has the first dishing 401. The semiconductor structure further includes air gap structures 901, where the air gap structures 901 are located on at least two sides of the second conductive structure 302 and the air gap structures 901 expose at least the first conductive sub-structure 3011 and a part of the barrier layer 501. A first dielectric layer 601 is located on the base 10 and covers the barrier layer 501; the air gap structures 901 are located in the first dielectric layer 601; and there is further a second dielectric layer 801 on the first dielectric layer 601, a third trench 203 passes through the first dielectric layer 601 and the second dielectric layer 801 and exposes the barrier layer 501, and the second conductive structure 302 fills the third trench 203. The second conductive structure 302 includes a third conductive sub-structure 3021 and a fourth conductive sub-structure 3022, the third conductive sub-structure 3021 covers a sidewall and the bottom of the third trench 203, and the fourth conductive sub-structure 3022 fills the third trench 203. The material of the barrier layer 501 may be one or more of tantalum, tantalum nitride, ruthenium, and ruthenium nitride. There may be two air gap structures 901, and the two air gap structures 901 are located on the two sides of the second conductive structure 302 and expose at least the first conductive sub-structure 3011 and the part of the barrier layer 501; or the air gap structures 901 may surround the second conductive structure 302 and the air gap structures 901 expose at least the first conductive sub-structure 3011 and the part of the barrier layer 501.

In this embodiment of this application, the barrier layer 501 is disposed to cover the first conductive structure 301. In this way, the barrier layer 501 can block diffusion of the first conductive structure 301, and prevent generation of electrochemical reaction and corrosion of a metal. Diffusion of copper and migration of copper at a corner position of the first conductive structure 301 are the most severe part. To further improve the performance of the semiconductor structure, in this application, the air gap structures 901 are disposed at the corner position of the first conductive structure 301. Existence of the air gap structures 901 provides enough space for a diffusion or migration phenomenon that possibly exists in the first conductive structure 301. Even if diffusion or migration exists in the first conductive structure 301, the diffusion or the migration occurs in the air gap structures 901. Because the air gap structures 901 have a good insulating effect, the diffusion or the migration of the first conductive structure 301 can be prevented from affecting the semiconductor structure. In other words, in this application, on the one hand, the barrier layer 501 is disposed to prevent the diffusion or the migration of the first conductive structure 301, and on the other hand, the air gap structures 901 are further disposed in a corner region in which diffusion and migration are the most severe, thereby improving the performance of the semiconductor structure by disposing both the barrier layer 501 and the air gap structures 901.

FIG. 5 is a schematic diagram of a semiconductor structure according to another embodiment of the present disclosure.

This embodiment differs from the previous embodiment in that: a barrier layer 501 in this embodiment of this application covers a first conductive structure 301 and further covers a part of a base 10. In other words, diffusion or migration that originally possibly exists at a junction position between the first conductive structure 301 and the base 10 is directly covered by the barrier layer 501, thereby further preventing occurrence of the diffusion or the migration. In addition, air gap structures 901 are further disposed at a corner position of the first conductive structure 301. There may be two air gap structures 901, which are located on two sides of a second conductive structure 302 and expose a corner of the first conductive structure 301. Alternatively, the air gap structures 901 may be disposed around the second conductive structure 302 and expose the corner of the first conductive structure 301. In comparison with the previous embodiment, the barrier layer 501 in this embodiment of this application further covers a first conductive sub-structure 3011 and the part of the substrate 10, to better prevent diffusion and migration of the first conductive structure 301, further prevent occurrence of electrochemical reaction, prevent corrosion of the first conductive structure 301 and the second conductive structure 302, and further improve the performance of the semiconductor structure and increase the yield thereof.

A person of ordinary skill in the art may understand that the foregoing implementations are specific embodiments for implementing the present disclosure. In actual application, various modifications may be made to the forms and details of the implementations without departing from the spirit and scope of the present disclosure. Any person skilled in the art may make changes and modifications without departing from the spirit and scope of the present disclosure. Therefore, the protection scope of the present disclosure shall be subject to the scope defined by the claims.

What is claimed is:

1. A fabrication method for a semiconductor structure, comprising:
providing a base, a first trench being formed on the base;
a first initial conductive structure filling the first trench and covering a surface of the base;
removing a part of the first initial conductive structure by adopting a first polishing process to form a first conductive structure, the first conductive structure being located in the first trench and a surface of the first conductive structure having a first dishing;
forming a barrier layer, the barrier layer covering at least the first dishing; and
forming a second conductive structure on the barrier layer, the second conductive structure being electrically connected to the barrier layer.

2. The fabrication method for a semiconductor structure according to claim 1, wherein the forming a barrier layer specifically comprises:
forming an initial barrier layer, wherein the initial barrier layer fills the first dishing and covers the base; and
removing a part of the initial barrier layer by adopting a second polishing process to form the barrier layer, wherein the barrier layer is located in the first dishing and a surface of the barrier layer has a second dishing.

3. The fabrication method for a semiconductor structure according to claim 2, wherein the first polishing process is a high dishing chemical mechanical polishing process, and the second polishing process is a low dishing chemical mechanical polishing process; and a dishing depth of the first dishing is H1, a dishing depth of the second dishing is H2, and H1 is greater than H2.

4. The fabrication method for a semiconductor structure according to claim 1, wherein the first conductive structure comprises a first conductive sub-structure and a second conductive sub-structure, the first conductive sub-structure covers a sidewall and a bottom of the first trench, and the second conductive sub-structure is located in the first trench and has the first dishing.

5. The fabrication method for a semiconductor structure according to claim 1, wherein after the barrier layer is formed and before the second conductive structure is formed, the method further comprises forming air gap structures, wherein the air gap structures expose at least the first conductive sub-structure and a part of the barrier layer.

6. The fabrication method for a semiconductor structure according to claim 5, wherein the forming an air gap structures specifically comprises: forming a first dielectric layer on the barrier layer, and removing a part of the first dielectric layer to form a second groove, wherein the second groove exposes at least the first conductive sub-structure and a part of the barrier layer; forming a sacrificial layer, wherein the sacrificial layer fills the second groove; forming a second dielectric layer (801) on the sacrificial layer and the first dielectric layer; and removing the sacrificial layer by adopting an ashing process to form the air gap structures, wherein the air gap structures are located in the first dielectric layer.

7. The fabrication method for a semiconductor structure according to claim 6, wherein after the air gap structures are formed, the method further comprises: forming a third trench, wherein the third trench is located between the air gap structures, and the third trench passes through the first dielectric layer and the second dielectric layer and exposes the barrier layer;
and forming the second conductive structure in the third trench, wherein the air gap structures are located on at least two sides of the second conductive structure.

8. The fabrication method for a semiconductor structure according to claim 7, wherein the second conductive structure comprises a third conductive sub-structure and a fourth conductive sub-structure, the third conductive sub-structure covers a sidewall and a bottom of the third trench, and the fourth conductive sub-structure fills the third trench.

9. The fabrication method for a semiconductor structure according to claim 1, wherein a material of the barrier layer may be one or more of tantalum, tantalum nitride, ruthenium, and ruthenium nitride.

10. The fabrication method for a semiconductor structure according to claim 4, wherein the barrier layer further covers the first conductive sub-structure and a part of the base.

11. The fabrication method for a semiconductor structure according to claim 5, wherein the air gap structures surround the second conductive structure and the air gap structures expose at least the first conductive sub-structure and a part of the barrier layer.

12. A semiconductor structure, comprising:
a base, the base having a first trench;
a first conductive structure, located in the first trench, and a surface of the first conductive structure having a first dishing;
a barrier layer, covering at least the first dishing; and
a second conductive structure, located above the barrier layer and electrically connected to the barrier layer.

13. The semiconductor structure according to claim 12, wherein a surface of the barrier layer has a second dishing, a dishing depth of the first dishing is H1, a dishing depth of the second dishing is H2, and H1 is greater than H2.

14. The semiconductor structure according to claim 12, wherein the first conductive structure comprises a first conductive sub-structure and a second conductive sub-structure, the first conductive sub-structure covers a sidewall and a bottom of the first trench, and the second conductive sub-structure is located in the first trench and has the first dishing.

15. The semiconductor structure according to claim 14, further comprising air gap structures, wherein the air gap structures are located on at least two sides of the second conductive structure and the air gap structures expose at least the first conductive sub-structure and a part of the barrier layer.

16. The semiconductor structure according to claim 15, further comprising a first dielectric layer, wherein the first dielectric layer is located on the base and covers the barrier layer; the air gap structures are located in the first dielectric layer; and there is further a second dielectric layer on the first dielectric layer, a third trench passes through the first dielectric layer and the second dielectric layer and exposes the barrier layer, and the second conductive structure fills the third trench.

17. The semiconductor structure according to claim 12, wherein the second conductive structure comprises a third conductive sub-structure and a fourth conductive sub-structure, the third conductive sub-structure covers a sidewall and a bottom of the third trench, and the fourth conductive sub-structure fills the third trench.

18. The semiconductor structure according to claim 12, wherein a material of the barrier layer may be one or more of tantalum, tantalum nitride, ruthenium, and ruthenium nitride.

19. The semiconductor structure according to claim 14, wherein the barrier layer further covers the first conductive sub-structure and a part of the base.

20. The semiconductor structure according to claim 15, wherein the air gap structures surround the second conductive structure and the air gap structures expose at least the first conductive sub-structure and a part of the barrier layer.
